(19) United States
(12) Patent Application Publication
(10) Pub. No.: US 2015/0147832 A1
(43) Pub. Date: May 28, 2015

(54) METHOD FOR PRODUCING LIGHT-EMITTING DIODE

(71) Applicant: LEXTAR ELECTRONICS CORPORATION, Hsinchu (TW)

(72) Inventors: Li-Cheng YANG, Taoyuan County (TW); Chun-Ying HUANG, Miaoli County (TW)

(73) Assignee: LEXTAR ELECTRONICS CORPORATION, Hsinchu (TW)

(21) Appl. No.: 14/266,767

(22) Filed: Apr. 30, 2014

(30) Foreign Application Priority Data
Nov. 22, 2013 (TW) 102142575

(51) Int. Cl. H01L 33/00

(52) U.S. Cl. CPC H01L 33/005; H01L 2933/0033
USPC 438/26

(57) ABSTRACT

A method for producing a light-emitting diode is provided, including the following steps. First, a carrier is provided, wherein the carrier comprises a die bonding surface. Then, a die bonding adhesive layer is formed on the die bonding surface, wherein the die bonding adhesive layer has a photoresist property. Next, at least one lighting chip is disposed on the die bonding adhesive layer, and an uncovered portion of the die bonding adhesive layer is not covered by the lighting chip. Finally, the uncovered portion of the die bonding adhesive layer is removed.

### CROSS REFERENCE TO RELATED APPLICATIONS

This Application claims priority of Taiwan Patent Application No. 102142575, filed on Nov. 22, 2013, the entirety of which is incorporated by reference herein.

### BACKGROUND OF THE INVENTION

1. Field of the Invention

The present invention relates to a method for producing a light-emitting diode, and in particular to a method for producing a light-emitting diode capable of controlling an area of a die bonding adhesive layer.

2. Description of the Related Art

The area of a die bonding adhesive layer can deeply affect the performance of a light-emitting diode. If the area of the die bonding adhesive layer is too small, heat generated by light chips may not be sufficiently transmitted to the carrier. If the area of the die bonding adhesive layer is too big, the die bonding adhesive layer may cover the light chips, and the light generated by the light chips may be absorbed by the die bonding adhesive layer. Conventionally, the die bonding adhesive layer is formed on the carrier via glue dropping, and the quantity of glue and the area of the die bonding adhesive layer cannot be controlled.

### BRIEF SUMMARY OF THE INVENTION

In one embodiment, a method for producing a light-emitting diode is provided, including the following steps. First, a carrier is provided, wherein the carrier comprises a die bonding surface. Then, a die bonding adhesive layer is formed on the die bonding surface, wherein the die bonding adhesive layer has a photoresist property. Next, at least one lighting chip is disposed on the die bonding adhesive layer, and an uncovered portion of the die bonding adhesive layer is not covered by the lighting chip. Finally, the uncovered portion of the die bonding adhesive layer is removed.

In another embodiment, a method for producing a light-emitting diode is provided, including the following steps. First, a carrier is provided, wherein the carrier comprises a die bonding surface. Then, a patterned photoresist layer is formed on the die bonding surface, wherein the patterned photoresist layer comprises an opening, and the die bonding surface is uncovered in the opening. Next, a die bonding adhesive layer is formed in the opening. Then, a lighting chip is disposed on the die bonding adhesive layer. Finally, the patterned photoresist layer is removed.

Utilizing the method for producing a light-emitting diode of the first embodiment of the invention, the area of the portion of the die bonding adhesive layer under each lighting chip is controlled to be smaller than or equal to the area of the lighting chip. Therefore, the bounding area is precisely controlled without becoming too big or too small. The heat generated by the lighting chip can be sufficiently transmitted to the carrier, and the light generated by the lighting chip would not be absorbed by the die bonding adhesive layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a flow chart of the method for producing a light-emitting diode of the first embodiment of the invention;

FIGS. 2A˜2E shows steps of the method for producing a light-emitting diode of the first embodiment of the invention;

FIG. 3 is a flow chart of the method for producing a light-emitting diode of the second embodiment of the invention;

FIGS. 4A˜4F shows steps of the method for producing a light-emitting diode of the second embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

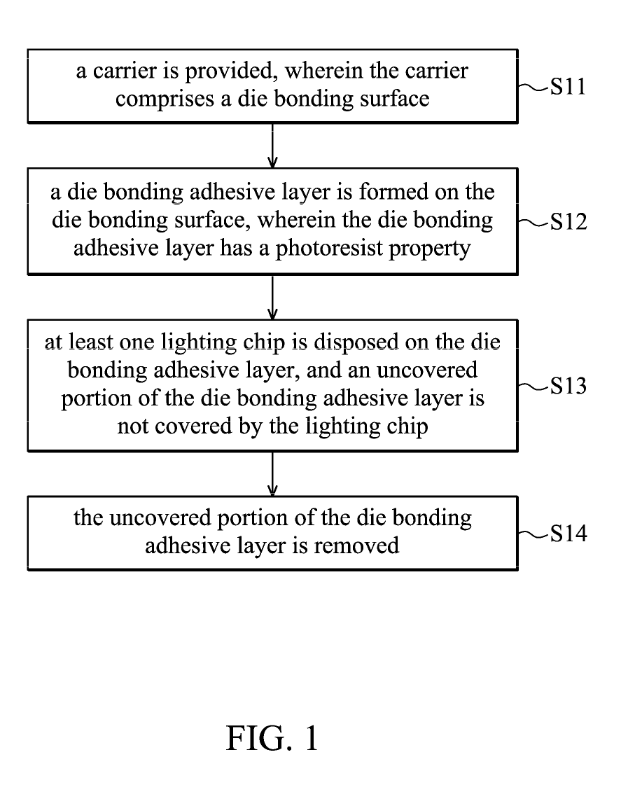

FIG. 1 shows a method for producing a light-emitting diode of a first embodiment of the invention, comprising the following steps. First, a carrier is provided, wherein the carrier comprises a die bonding surface (S11). Then, a die bonding adhesive layer is formed on the die bonding surface, wherein the die bonding adhesive layer has a photoresist property (S12). Next, at least one lighting chip is disposed on the die bonding adhesive layer, and an uncovered portion of the die bonding adhesive layer is not covered by the lighting chip (S13). Finally, the uncovered portion of the die bonding adhesive layer is removed (S14).

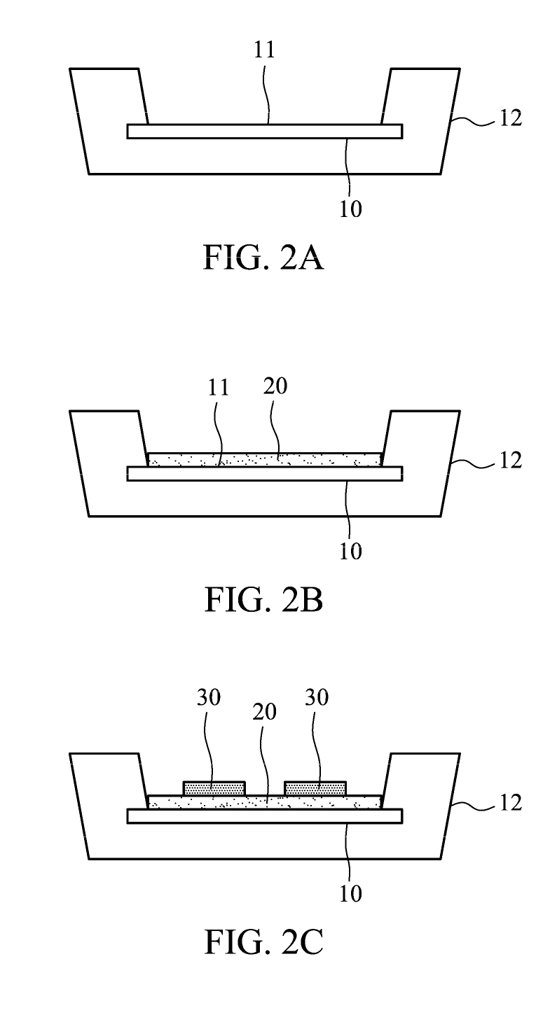

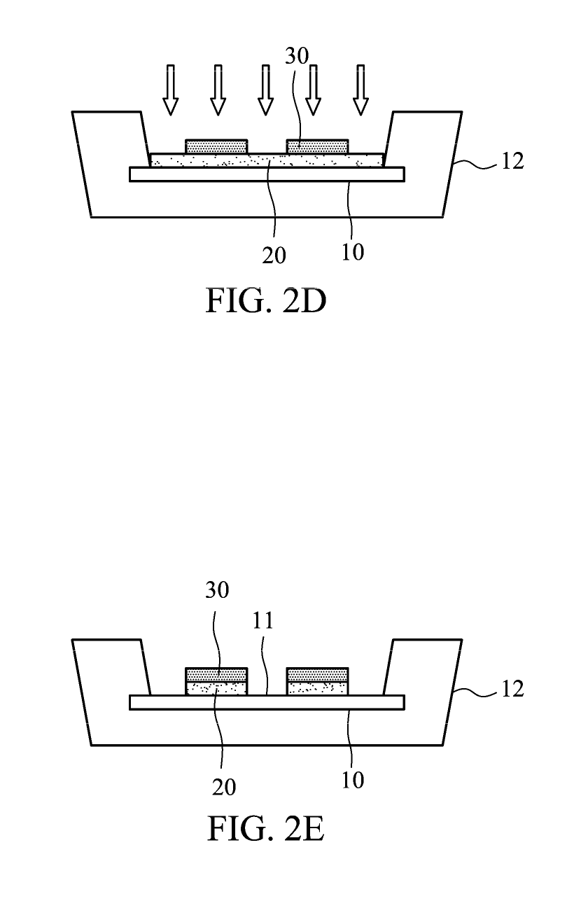

FIG. 2A shows step S11 of the first embodiment of the invention, wherein the carrier 10 comprises the die bonding surface 11. In this embodiment, a plastic cup 12 is provided. The carrier 10 is embedded in the plastic cup 12, and the die bonding surface 11 is uncovered. The carrier 10 comprises metal or metallic oxide to increase heat conductivity.

FIG. 2B shows step S12 of the first embodiment of the invention, wherein the die bonding adhesive layer 20 with a photoresist property is formed on the die bonding surface 11. In this embodiment, the die bonding adhesive layer 20 comprises positive photoresist material.

FIG. 2C shows step S13 of the first embodiment of the invention, wherein the lighting chips 30 are disposed on the die bonding adhesive layer 20, and an uncovered portion of the die bonding adhesive layer 20 (for example, the portion of the die bonding adhesive layer between the lighting chips, or the portion of the die bonding adhesive layer between the lighting chips and the plastic cup 12) is not covered by the lighting chips 30.

In one embodiment, the step of removing the exposed portion of the die bonding adhesive layer (S14) further comprises the following steps. First, a photolithography process is performed with the lighting chips as a mask, wherein the uncovered portion of the die bonding adhesive layer is exposed. Then, an anisotropic etching is performed to remove the exposed uncovered portion of the die bonding adhesive layer.

FIGS. 2D˜2E show step S14 of the first embodiment of the invention. First, in FIG. 2D, the photolithography process is performed, and the uncovered portion of the die bonding adhesive layer 20 is exposed. Then, in FIG. 2E, the anisotropic etching is performed to remove the exposed uncovered portion of the die bonding adhesive layer 20. With reference to FIG. 2E, after the photolithography process and the anisotropic etching, an area of the portion of the die bonding adhesive layer 20 under each lighting chip 30 is smaller than or equal to an area of the lighting chip 30.

Utilizing the method for producing a light-emitting diode of the first embodiment of the invention, the area of the portion of the die bonding adhesive layer under each lighting chip is controlled to be smaller than or equal to the area of the lighting chip. Therefore, the bounding area is precisely controlled without becoming too big or too small. The heat generated by the lighting chip can be sufficiently transmitted to the carrier, and the light generated by the lighting chip would not be absorbed by the die bonding adhesive layer.

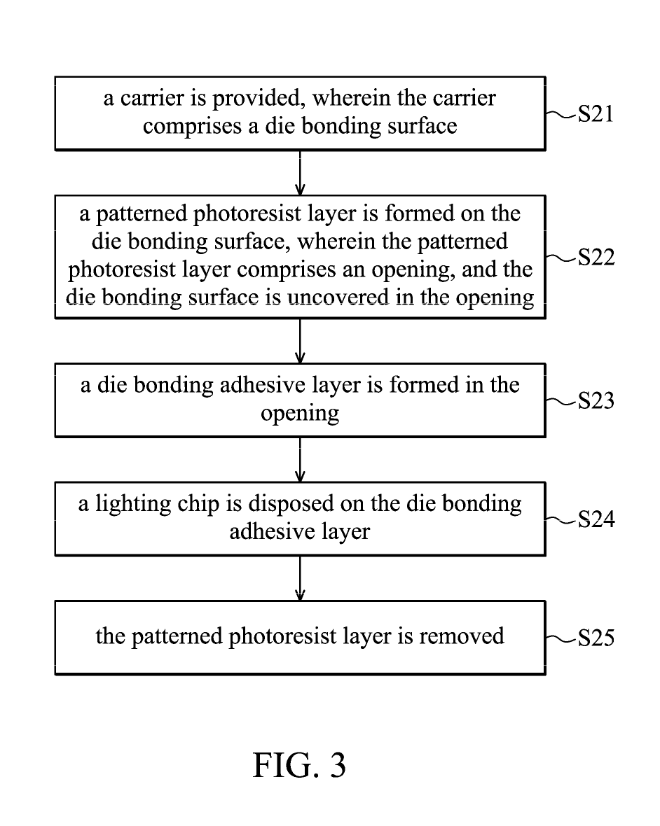

FIG. 3 shows a method for producing a light-emitting diode of a second embodiment of the invention, comprising the following steps. First, a carrier is provided, wherein the carrier comprises a die bonding surface (S21). Then, a patterned photoresist layer is formed on the die bonding surface, wherein the patterned photoresist layer comprises an opening, and the die bonding surface is uncovered in the opening (S22). Next, a die bonding adhesive layer is formed in the opening (S23). Then, a lighting chip is disposed on the die bonding adhesive layer (S24). Finally, the patterned photoresist layer is removed (S25).

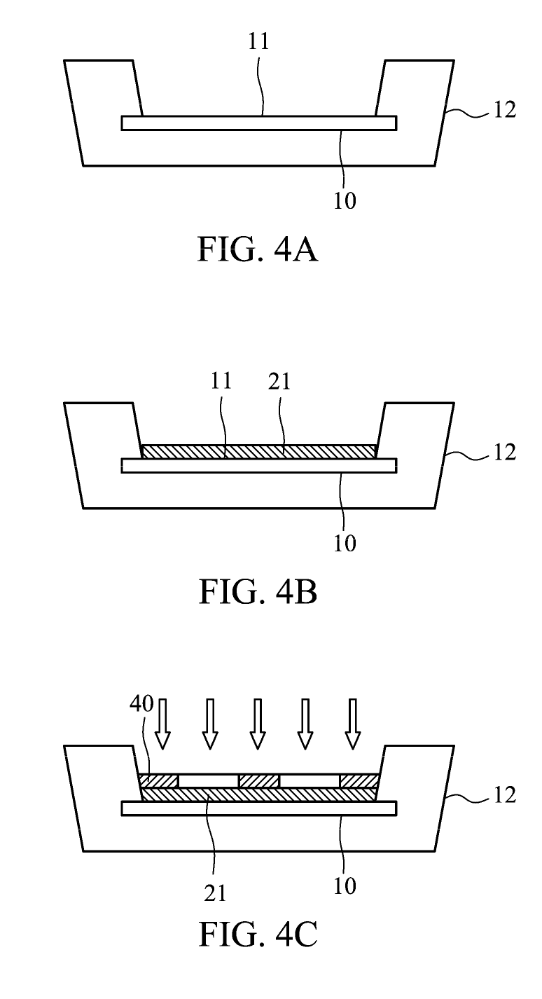

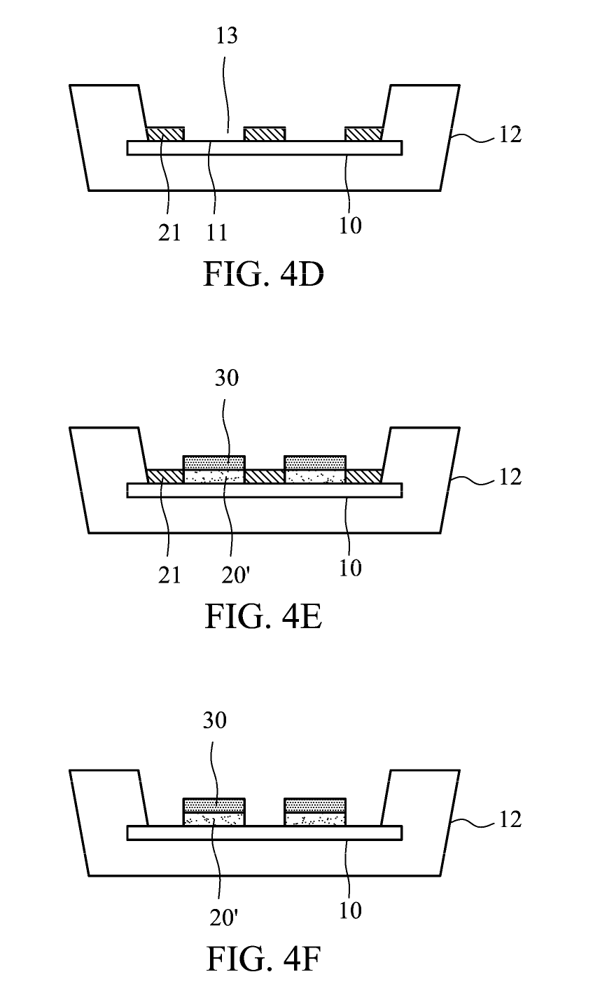

FIG. 4A shows step S21 of the second embodiment of the invention, wherein the carrier 10 comprises the die bonding surface 11. In this embodiment, a plastic cup 12 is provided. The carrier 10 is embedded in the plastic cup 12, and the die bonding surface 11 is uncovered. The carrier 10 comprises metal or metallic oxide to increase heat conductivity.

FIGS. 4B˜4D show step S22 of the second embodiment of the invention. First, a photoresist layer 21 is formed on the die bonding surface 11 (FIG. 4B). Then, the photoresist layer 21 is exposed under a mask layer 40 (FIG. 4C). Finally, the exposed photoresist layer 21 is etched to form the patterned photoresist layer (FIG. 4D). The patterned photoresist layer comprises an opening 13, and the die bonding surface 11 is uncovered in the opening 13. In this embodiment, the exposed photoresist layer 21 comprises positive photoresist material. However, the invention is not limited thereby. A negative photoresist material can be utilized in the embodiment of the invention incorporated with different mask designs.

FIG. 4E shows the steps S23˜S24 of the second embodiment of the invention, wherein the die bonding adhesive layer 20′ is formed in the opening 13, and the lighting chips 30 are disposed on the die bonding adhesive layer 20′.

FIG. 4F shows step S25 of the second embodiment of the invention, wherein the patterned photoresist layer 21 is removed.

Utilizing the method for producing a light-emitting diode of the second embodiment of the invention, the area of the portion of the die bonding adhesive layer under each lighting chip is controlled to be smaller than or equal to the area of the lighting chip. Therefore, the bounding area is precisely controlled without becoming too big or too small. The heat generated by the lighting chip can be sufficiently transmitted to the carrier, and the light generated by the lighting chip would not be absorbed by the die bonding adhesive layer.

After the steps mentioned above, a wire bonding step and a package step can be performed on the light chip.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for producing a light-emitting diode, comprising:
providing a carrier, the carrier comprising a die bonding surface;
forming a die bonding adhesive layer on the die bonding surface, wherein the die bonding adhesive layer with a photoresist property;
disposing a lighting chip on the die bonding adhesive layer, wherein an exposed portion of the die bonding adhesive layer is not covered by the lighting chip; and
removing the uncovered portion of the die bonding adhesive layer.

2. The method for producing a light-emitting diode as claimed in claim 1, wherein the step of removing the exposed portion of the die bonding adhesive layer comprises:
performing a photolithography process with the lighting chip as a mask, wherein the uncovered portion of the die bonding adhesive layer is exposed; and
performing an anisotropic etching to remove the exposed uncovered portion of the die bonding adhesive layer.

3. The method for producing a light-emitting diode as claimed in claim 2, wherein after the photolithography process and the anisotropic etching, an area of a portion of the die bonding adhesive layer under the lighting chip is smaller than or equal to an area of the lighting chip.

4. The method for producing a light-emitting diode as claimed in claim 3, wherein the carrier comprises metal or metallic oxide.

5. The method for producing a light-emitting diode as claimed in any one of claims 1, wherein the carrier further comprises a plastic cup, the carrier is embedded in the plastic cup, and the die bonding surface is uncovered.

6. A method for producing a light-emitting diode, comprising:
providing a carrier, the carrier comprising a die bonding surface;
forming a patterned photoresist layer on the die bonding surface, wherein the patterned photoresist layer comprises an opening and the die bonding surface is exposed within the opening;
forming a die bonding adhesive layer in the opening;
disposing a lighting chip on the die bonding adhesive layer; and
removing the patterned photoresist layer.

7. The method for producing a light-emitting diode as claimed in claim 6, wherein an anisotropic etching is performed to remove the patterned photoresist layer

8. The method for producing a light-emitting diode as claimed in claim 7, wherein after removing the patterned photoresist layer, an area of a portion of the die bonding adhesive layer under the lighting chip is smaller than or equal to an area of the lighting chip.

9. The method for producing a light-emitting diode as claimed in claim 8, wherein the carrier comprises metal or metallic oxide.

10. The method for producing a light-emitting diode as claimed in any one of claims 6, wherein the carrier further comprises a plastic cup, the carrier is embedded in the plastic cup, and the die bonding surface is uncovered.
